(19) United States
(12) Patent Application Publication
(10) Pub. No.: US 2025/0210942 A1
(43) Pub. Date: Jun. 26, 2025

(54) LASER EMITTING ARRAYS WITH THERMALLY-INDUCED ENHANCED SPECTRAL WIDTH

(71) Applicant: Apple Inc., Cupertino, CA (US)

(72) Inventors: Sansaptak Dasgupta, San Jose, CA (US); Fei Tan, Sunnyvale, CA (US); Gidi Lasovski, Ramat Hasharon (IL); Takashi Hosoda, Sunnyvale, CA (US); Rui Liang, Santa Clara, CA (US); Yuval Tsur, Tel Aviv (IL); Siddharth Joshi, Saint-Egreve (FR); Weiping Li, Pleasanton, CA (US); Refael Della Pergola, Tel Aviv (IL)

(21) Appl. No.: 18/967,392

(22) Filed: Dec. 3, 2024

Related U.S. Application Data
(60) Provisional application No. 63/613,609, filed on Dec. 21, 2023.

(51) Int. Cl. H01S 5/42; H01S 5/042; H01S 5/06; H01S 5/183; H01S 5/187

(52) U.S. Cl. CPC H01S 5/423; H01S 5/0421; H01S 5/0612; H01S 5/18361; H01S 5/187

(57) ABSTRACT

Embodiments are directed to electronic devices that include a surface emitting laser array including a first set of light emitters distributed across the surface emitting laser array and configured to emit laser light into an environment of the electronic device. The laser array can also include a second set of light emitters interspersed with the first set of light emitters, where each light emitter in the second set of light emitters includes a first set of layers defining a first mirror, a second set of layers defining a second mirror, and a third set of layers positioned between the first set of layers and the second set of layers and defining a laser cavity. The surface emitting laser array can include a light blocking material positioned on one or more of the second set of light emitters and configured to cause localized heating of the laser array.

### CROSS REFERENCE TO RELATED APPLICATION

This application is a nonprovisional and claims the benefit under 35 U.S.C. § 119(e) of U.S. Provisional Patent Application No. 63/613,609, filed Dec. 21, 2023, the contents of which are incorporated herein by reference as if fully disclosed herein.

### FIELD

The described embodiments relate generally to structures and configurations for surface emitting laser arrays that may be used to emit light into an environment and/or detect returned light to determine an object distance, location, speed, velocity, motion or displacement. In particular, described embodiments relate to surface emitting laser arrays that use thermal effects to modify emitted light.

### BACKGROUND

Electronic devices may be provided with various kinds of sensors for sensing local or remote environments of the electronic device. Local environment sensing may be used to detect, for example, a user input, whereas remote environment sensing may be used to detect, for example, a property of the device's user (e.g., a user biometric) or a distance to an object.

### SUMMARY

Embodiments are directed to an electronic device that includes a surface emitting laser array. The surface emitting laser array can include a first set of light emitters distributed across the surface emitting laser array and configured to emit laser light into an environment of the electronic device, and a second set of light emitters interspersed with the first set of light emitters. Light emitters in the second set of light emitters can include a first set of layers defining a first mirror, a second set of layers defining a second mirror, and a third set of layers positioned between the first set of layers and the second set of layers and defining a laser cavity. The surface emitting laser array may include a light blocking material positioned on one or more light emitters of the second set of light emitters and be configured to reflect light generated by a respective light emitter of the second set of light emitters back into the surface emitting laser array. The electronic device may include a processor configured to control operation of the first set of light emitters and the second set of light emitters.

Embodiments are also directed to surface emitting laser arrays that include a first set of light emitters distributed across the surface emitting laser array and configured to emit laser light and a second set of light emitters interspersed with the first set of light emitters and configured to emit laser light. Each light emitter of the second set of light emitters can include a first set of layers defining a first mirror, and a second set of layers positioned on the first set of layers. The second set of layers defining a laser cavity and a first portion of a trench at least partially surrounding a respective light emitter. Each light emitter of the second set of light emitters can include a third set of layers positioned on the second set of layers. The third set of layers defining a second mirror and a second portion of the trench. Each of the second set of light emitters can also include a heating element positioned within the trench and configured to adjust an operating temperature of one or more of the second set of light emitters.

Embodiments further include an electronic device that includes a surface emitting laser array that includes a first set of light emitters distributed across the surface emitting laser array. The first set of light emitters can include first electrical contacts and be configured to emit laser light. The surface emitting laser array can include a second set of light emitters interspersed with the first set of light emitters. Each light emitter in the second set of light emitters can include a first set of layers defining a first mirror, a second set of layers positioned on the first set of layers and defining a laser cavity, and a third set of layers positioned on the second set of layers and defining a second mirror. Each of the second set of light emitters can include a second electrical contact positioned on the third set of layers and defining an opening configured to allow laser light to be emitted from a respective light emitter, and a heating element positioned on the third set of layers and configured to increase an operating temperature of a respective emitter of the second set of light emitters. The electronic device can include a processor configured to control operation of the first set of light emitters, the second set of light emitters and heating elements of the second set of light emitters.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows an example electronic device that can include a surface emitting laser array;

FIG. 2 shows an example surface emitting laser array, as described herein;

FIG. 3 shows an example diagram of a surface emitting laser that may be incorporated into a laser array, as described herein;

FIG. 4A shows a top view of an example surface emitting laser array that includes a light blocking material;

FIG. 4B shows a cross-section view of the example surface emitting laser array shown in FIG. 4A;

FIG. 5A shows a top view an example surface emitting laser array that includes one or more heating elements positioned around emitters of the array;

FIG. 5B shows a cross-sectional view of the example surface emitting laser array shown in FIG. 5A;

FIG. 6A shows an example surface emitting laser array that includes heating elements positioned within the structure of the array;

FIG. 6B shows a cross-sectional view of the example surface emitting laser array shown in FIG. 6A;

FIG. 7 shows a block diagram of an electronic device, as described herein.

It should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications and equivalents as can be included within the spirit and scope of the described embodiments as defined by the appended claims.

Embodiments disclosed herein are directed to surface emitting laser arrays that use thermal effects to modify the spectrum of light emitted by the laser array. The surface emitting laser arrays may include one or more heating elements positioned at different locations of the laser array. The heating element(s) may be operated to increase a temperature of a localized region of the laser array, which may result in modifying the wavelengths of light emitted by one or more light emitters in the localized region. The modification of the wavelengths emitted by some of the light emitters may result in an increase in the spectral width (i.e., the range of emitted wavelengths) of light emitted from the laser array.

A surface emitting laser array may be used to emit light into an environment, and returned light may be sensed by the laser array and/or other sensors. The emitted light may impinge on one or more objects in the environment and some of the light may be returned to the sensor(s). In some cases, emitting light having a narrower spectral width may result in the detection of interference fringes that occur within the returned light. The interference fringes may add artifacts to sensed light, which may need to be accounted for when determining parameters of the environment (e.g., distance of an object, speed of an object, depth profile, etc.) using the sensed light.

In some embodiments, using thermal effects to increase the spectral width of light emitted from the laser array may reduce the interference fringes in the sensed light, which may help improve a quality of sensed light and/or reduce the prost processing complexity that results from the interference fringes.

In some embodiments, a light blocking material may be used to cover one or more light emitters of a surface emitting laser array. The light blocking material may reflect all or substantially all of the laser light emitted by a particular emitter back into the emitter, which may cause a local increase in temperature at the region of the blocked emitter. Accordingly, operation of the blocked light emitter may result in a localized increase in the temperature of the surface emitting laser array, which may increase an operating temperature of un-blocked light emitters nearby. The increase in the operating temperature of the unblocked light emitters causes a change in the wavelength spectrum emitted by these emitters, which may result in changes to the overall emission spectrum of the laser array. Operation of the blocked light emitters may be used to control the change in the emissions spectrum. For example, the blocked light emitters may be operated to cause an increase in the spectral width of light emitted from the laser array.

In some embodiments, a heating element may be positioned within the structure of the surface emitting laser array. For example, during manufacturing, a trench may be formed as part of a laser emitter structure. The trench may extend through one or more layers and/or structures of a laser emitter of the laser array. For example, a trench may extend into a first mirror structure (e.g., an upper distributed Bragg reflector), a lasing cavity and/or a lower mirror structure (e.g., a lower distributed Bragg reflector). An electrically conductive heating element may be placed in the trench and may be embedded or otherwise contained within the laser array by one or more layers placed on top of the heating element. The heating element may be electrically coupled to a current source which can control operation of one or more heating elements. For example, multiple emitters may each have a respective heating element positioned within a trench. The heating elements may be distributed throughout the laser array. The heating elements may be operated to locally increase the operating temperature of different portions of the array and change the emissions spectrum of light emitted from the array. For example, the heating elements may be operated to cause an increase in the spectral width of light emitted from the laser array.

In other embodiments, one or more heating elements may be positioned on top of a surface emitting laser array at various locations. The heating element may surround an optical opening in which laser light is emitted from a light emitter so as to allow light to be emitted and/or sensed by a respective light emitter. The heating element may be electrically coupled to a current source, which may control operation of one or more heating elements. For example, multiple emitters may each have a respective heating element positioned within a trench. The heating elements may be distributed throughout the laser array. The heating elements may be operated to locally increase the operating temperature of different portions of the array and change the emissions spectrum of light emitted from the array. For example, the heating elements may be operated to cause an increase in the spectral width of light emitted from the laser array.

The surface emitting laser array may be incorporated into an electronic device such as a smartphone, smartwatch, a laptop computing device, a tablet, other portable and/or wearable electronic devices, desktop computers, displays/monitors, smart TV, smart home devices, and/or any other suitable electronic devices. The electronic device may control operation of the surface emitting laser to locally heat regions of the laser array and emit and/or detect light using the surface emitting laser array. The electronic device may emit and/or detect light using one or more surface emitting laser arrays to determine parameters of an environment and/or objects located within an environment as described herein. In some embodiments the laser arrays can include vertical cavity surface emitting laser (VCSEL) arrays, horizontal cavity surface emitting laser (HCSEL) arrays and/or other suitable laser arrays.

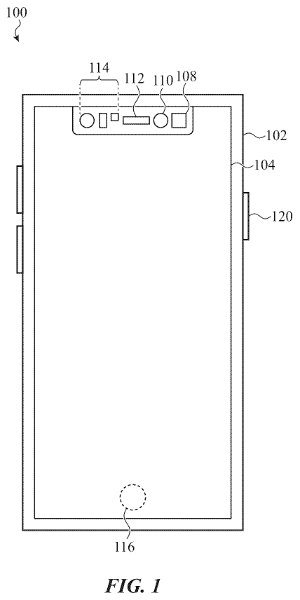

These and other embodiments are discussed below with reference to FIGS. 1-7. However, those skilled in the art will readily appreciate that the detailed description given herein with respect to these Figures is for explanatory purposes only and should not be construed as limiting.

FIG. 1 shows an example electronic device 100 that can include one or more surface emitting laser arrays 108, which may also be referred to as a “laser array.” The dimensions and form factor of the electronic device 100, including the ratio of the length of its long sides to the length of its short sides, suggest that the electronic device 100 is a mobile phone (e.g., a smartphone). However, the device's dimensions and form factor are arbitrarily chosen, and the electronic device 100 could alternatively be any portable electronic device including, for example a mobile phone, tablet computer, portable computer, portable music player, wearable device (e.g., an electronic watch, health monitoring device, or fitness tracking device), augmented reality (AR) device, virtual reality (VR) device, mixed reality (MR) device, gaming device, portable terminal, digital single-lens reflex (DSLR) camera, video camera, vehicle navigation system, robot navigation system, or other portable or mobile device. The electronic device 100 could also be a device that is semi-permanently located (or installed) at a single location.

The electronic device 100 may include a housing 102 that at least partially surrounds a display 104. The housing 102 may include or support a front cover that defines a front surface of the electronic device 100, and/or a back cover that defines a back surface of the electronic device 100 (with the back surface opposite the front surface). More generically, the electronic device 100 may include one or more “covers.”

In some embodiments, the display 104 may be attached to (or abut) the housing 102 and/or the front cover. The display 104 may include one or more light-emitting elements, and in some cases may be a light-emitting diode (LED) display, an organic LED (OLED) display, a liquid crystal display (LCD), an electroluminescent (EL) display, a thin film transistor (TFT) display, or another type of display. In some embodiments, the display 104 may include, or be associated with, one or more touch and/or force sensors that are configured to detect a touch and/or a force applied to a surface of the front cover.

The electronic device 100 may have an optoelectronic device having one or more surface emitting laser arrays 108. The laser emitters of the laser arrays may be a vertical-cavity surface-emitting laser (VCSEL), a vertical external-cavity surface-emitting laser (VECSEL), a horizontal cavity surface-emitting laser (HCSEL), a quantum-dot laser (QDL), a quantum cascade laser (QCL), or an edge-emitting laser (EEL).

The laser array(s) 108 may be positioned on a “front side” of the electronic device 100 such that light emitted from the laser array 108 is directed at a user of the electronic device, when the user is looking at the display 104. Additionally or alternatively, the laser array 108 may be positioned on a “back side” of the electronic device 100 or at any other suitable location.

The electronic device 100 may include one or more front-facing cameras 110, speakers 112, microphones, or other components 114 (e.g., audio, imaging, and/or sensing components) that are configured to transmit or receive signals to/from the electronic device 100. In some cases, a front-facing camera 110, alone or in combination with other sensors, may be configured to operate as a bio-authentication or facial recognition sensor. In some embodiments, the facial recognition sensor may include an optoelectronic device. The electronic device 100 may also include various input devices, including a mechanical or virtual button 116, which may be accessible from the front surface (or display surface) of the electronic device 100. In some embodiments, a virtual button 116 may be displayed on the display 104 and, in some cases, a fingerprint sensor may be positioned under the button 116 and be configured to image a fingerprint through the display 104. In some embodiments, the fingerprint sensor or another form of imaging device may span a greater portion, or all, of the display area.

The electronic device 100 may also include buttons or other input devices positioned along the sidewall and/or on a back surface of the electronic device 100. For example, a volume button or multipurpose button 120 may be positioned along the sidewall, and in some cases may extend through an aperture in the sidewall. In other embodiments, the button 120 may take the form of a designated and possibly raised portion of the sidewall, and may not extend through an aperture in the sidewall.

In some embodiments, the back surface of the electronic device 100 may include a rear-facing camera that includes one or more image sensors. In some cases, the electronic device 100 may have a second imaging sensor, which may be an autofocus camera, a telephoto camera, a second camera used in conjunction with the rear-facing camera—such as to provide depth or 3D imaging—or another optical sensor. The electronic device 100 may also have a flash or light source that may be positioned on the back of the electronic device 100 (e.g., near the rear-facing camera). In some cases, the back surface of the electronic device 100 may include multiple rear-facing cameras. One or both of the rear-facing camera and the second imaging sensor may include one or more optoelectronic devices having an array of laser emitters, similar to those described above.

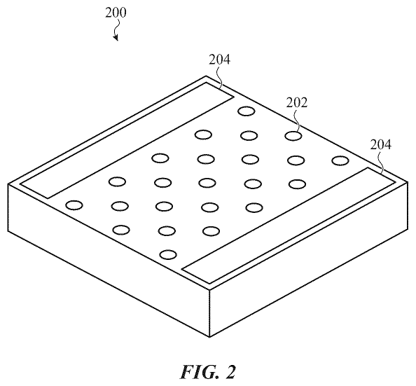

FIG. 2 shows an example surface emitting laser array 200, as described herein. The surface emitting laser array can include multiple light emitters 202 (one of which is labeled for clarity). Each of the light emitters may be formed from one or more layers that define the laser resonator structure for each of the light emitters 202, as described herein. For example, each light emitter may include a lower distributed Bragg reflector, a lasing cavity, and an upper distributed Bragg reflector, which are described in greater detail herein. In some cases, the surface emitting laser array 200 may include electrical contacts 204, which may be used to provide electrical current to control operation of one or more of the light emitters and/or operation of one or more heating elements as described herein.

The light emitters 202 may be arranged in various configurations to emit light having a defined emission pattern, emission spectrum, and/or other spatial variations of the emitted light. For example, the arrangement of the light emitters 202 may define an overall spatial emission profile for the laser array 200. In some cases, the light emitters 202 may be configured to generate a sustainably circular light emission profile, in which the wavelength, intensity and/or other properties of the emitted light may vary based on the radial distance from a central axis of a respective light emitter. In other cases, the light emitters 202 may be arranged with respect to each other to generate any other suitable emission profile.

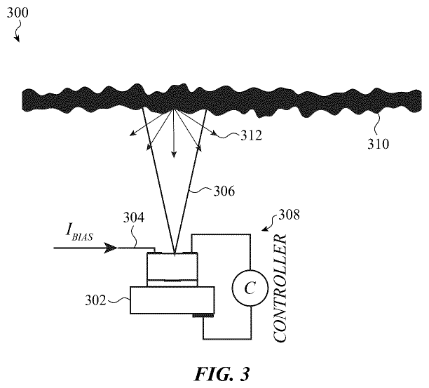

FIG. 3 shows an example diagram of a surface emitting laser 300 that may be incorporated into a laser array, as described herein. The surface emitting laser 300 may also be referred to here as a “light emitter.” The surface emitting laser array 300 makes use of a VCSEL diode 302 configured to emit laser light 306, which laser light may be directed toward an object 310. The VCSEL diode 302 may emit the laser light 306 under a forward voltage bias (or just “forward bias”) of its diode structure. During such forward bias, a bias current I_{BIAS} 304, flows through the VCSEL diode 302. Charge carriers crossing the p-n junction of the VCSEL diode 302 induce emission of laser light from the VCSEL diode 302. There may be reflections 312 of the emitted laser light 306, which may travel in multiple directions from the object 310.

The VCSEL diode 302 may be electrically connected to a controller 308. The controller 308 may be configured to control emission of the laser light from the VCSEL diode 302, as well as control a localized temperature in the region of the VCSEL diode 302 by controlling operation of one or more heating elements, as discussed in greater detail herein.

The controller 308 may communicate, either directly or indirectly, with some or all of the other components of the laser array 300 and/or the electronic device 100. The controller 308 may be implemented as any electronic device or circuit capable of processing, receiving, or transmitting data or instructions, whether such data or instructions is in the form of software or firmware or otherwise encoded. For example, the controller 308 may include a microprocessor, a central processing unit (CPU), an application-specific integrated circuit (ASIC), a digital signal processor (DSP), a controller, or a combination of such devices. As described herein, the term “controller” is meant to encompass a single processor or processing unit, multiple processors, multiple processing units, or other suitably configured computing element or elements. In some cases, the controller 308 may provide part or all of the processing system or processor described herein. The controller 308 may be communicatively coupled to a memory for storing electronic and sensor data, and the memory may be a random-access memory, read-only memory, Flash memory, removable memory, other types of storage elements, or combinations of such memory types.

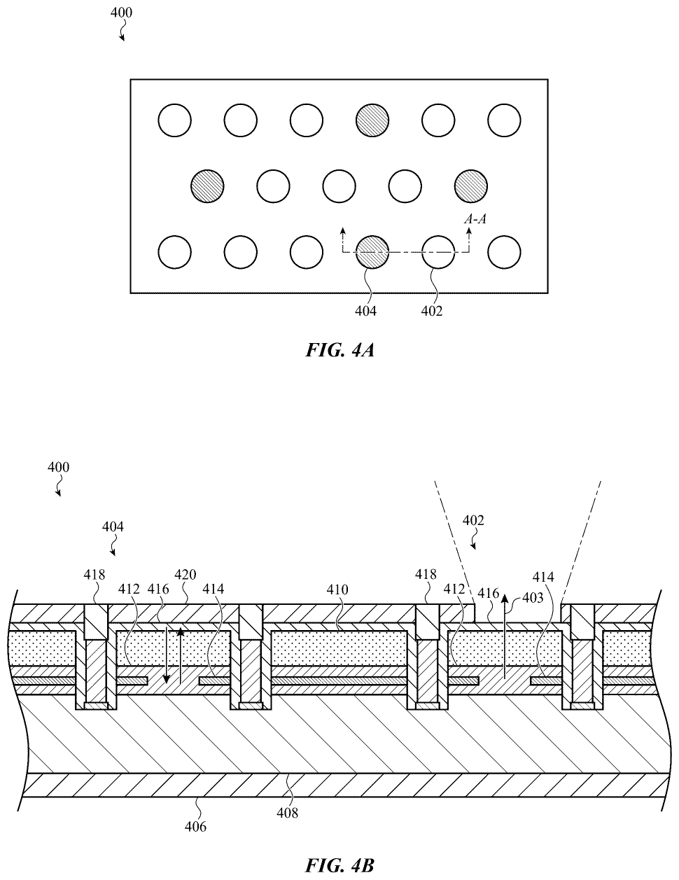

FIG. 4A shows a top view of an example surface emitting laser array 400, as described herein. The laser array 400 can include a first set of light emitters 402 (one of which is labeled) and a second set of light emitters 404 (one of which is labeled) interspersed with the first set of light emitters 402. A light blocking material 420 (shown in FIG. 4B) may be positioned over each of the second set of light emitters 404 and be configured to reflect light generated by a respective second light emitter 404 back into the laser array 400. The reflection of light by the light blocking material 420 may cause a localized increase in temperature of the laser array at the region of the second light emitter 404. The localized increase in temperature may increase an operating temperature of one or more adjacent first emitters 402, which may modify one or more properties of light emitted from the one or more adjacent first emitters 402. For example, the increased operating temperature of a first emitter 402 may cause a shift in the wavelength of light emitted by the first emitter 402. This localized shift of the wavelength in some of the first emitters 402 (e.g., the ones adjacent the second emitter), may increase an overall spectral width of light emitted from the surface emitting laser array 400.

FIG. 4B shows a cross-section view taken along line A-A of the surface emitting laser array 400 shown in FIG. 4A. The laser array 400 may include a cathode layer 406, which may extend across multiple emitters 402 and 404 of the laser array 400. In some cases, the cathode layer 406 may define a bottom substrate of the laser array 400.

The laser array 400 may also include a first mirror 408, which may be formed from one or more layers and have a first reflectivity. The laser array may also include a second mirror 410, which may be formed from one or more layers and have a second reflectivity. In some cases, each of the first mirror 408 and the second mirror 410 may be configured as distributed Bragg reflectors (DBR). The first mirror 408 (first DBR) and/or the second mirror 410 (second DBR) may be fully or partially reflective. For example, the first mirror 408 (first DBR) may be configured with a higher reflectivity, which may reflect substantially all light generated by an emitter. The second mirror 410 (second DBR) may be configured with a lower reflectivity, which may allow light to leak from the top of the corresponding light emitter. In some cases, one or more emitters (e.g., VCSEL structures) of the laser array 400 can have multiple active regions, which may also be referred to as a multi-junction VCSEL. The multiple active regions can be separated by multiple oxidation layers.

A light emitter 402 and/or 404 has a p-n diode structure with the cathode section 406 and an anode section 418. The cathode section 406 is disposed on the bottom surface of laser array 400. The dielectric layer 416 may be disposed over the top surface and around the anode section 418 in order to isolate the anode section 418 from a bias current flowing into a light emitting diode 402, 404.

The laser array 400 may also include a laser cavity 412, which may generate laser light that is emitted by a light emitter. In some cases, the laser cavity 412 can include an oxide layer 414, which can define an optical aperture that shapes laser light generated by the laser cavity and emitted from the light emitter. The laser array 400 may also include a dielectric layer 416 and one or more anode pads 418. For example, each light emitter 402 and 404 may include anode pads 418 which extend from an upper surface of the laser array 400 and into a trench formed around a respective light emitter. The anode pads 418 may be used to supply electrical current to a respective light emitter to generate laser light.

As shown in FIG. 4B, each first light emitter 402 may include an opening, which may be defined by a respective anode pad 418, which allows laser light 403 generated by the first light emitter to be emitted from the laser array 400. The total light output generated by the laser array 400 may be a combination of the laser light generated by each first laser emitter 402.

As shown in FIG. 4B, each second light emitter 404 may be covered by a light blocking material 420, which reflects light generated by the second emitter 404 back into the laser array in the region of the second emitter 404. The reflection of light back into the second light emitter 404 may increase a temperate at that region of the laser array 400, which may also increase a temperature of other light emitters (e.g., light emitters 402 and/or 404) that are positioned around the second light emitter 404.

In some cases, the light blocking material 420 may block substantially all of the light generated by the respective second light emitter 404. In other cases, the light blocking material 420 may be configured to only block some of the light generated by the respective second light emitter 404. The light blocking material 420 may include a metal material, which may be the same or different from the anode pad(s) 418. Example metal materials include gold, aluminum, titanium, nickel chromium, tungsten, metal alloys, and/or any other suitable metal materials. In some cases, the light blocking material 420 may include other materials such as ceramics, dielectric materials, polymers and/or other suitable non-metallic materials, and/or materials including both metals and non-metals.

Operation of the second light emitters 404 may be controlled to heat one or more adjacent first light emitters and cause a modification to the overall light emitted from the laser array 400. For example, the duty cycle of a second light emitter 404 may be operated to cause a defined increase in temperature of the second light emitter 404, which may increase an operating temperate of one or more adjacent first light emitters 402. The increase in the operating temperature of a portion of the first light emitters 402 in the laser array 400, may shift a wavelength(s) of light emitted from the first light emitters 402 thereby causing different portions of light emitters to emit different wavelengths (or wavelength ranges) of light. Accordingly, the overall spectral width of light emitted from the laser array 400 may be increased.

The positioning of the second light emitters 404 (with light blocking material 420) may be configured to cause particular spatial shifts in the spectral emission across the laser array 400. For example, the second light emitters 404 may be positioned throughout the laser array 400 to cause particular regions of the laser array 400 to have specific shifts in the emitted light.

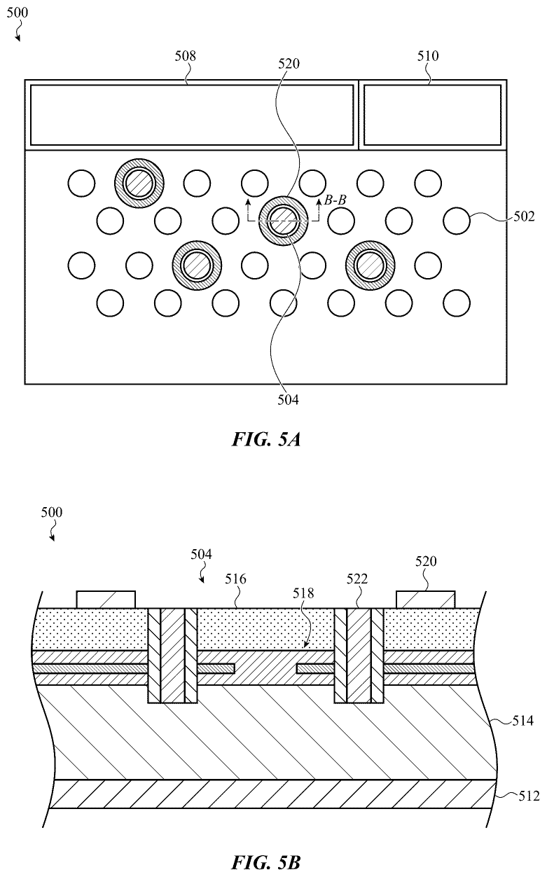

FIG. 5A shows a top view of an example surface emitting laser array 500, as described herein. The laser array 500 may include one or more heating elements 520 positioned around particular light emitters of the array. For example, the laser array 500 may include first light emitters 502 that do not include a heating element 520 and second light emitters 504 that have a heating element 520. The heating elements may cause localized heating of the laser array 500, which may increase an operating temperature of a corresponding second emitter 504, and in some cases, adjacent first emitters 502. The localized heating of the laser array 500 may modify light emitted by the array, for example, to increase a spectral width of light emitted from the laser array 400, as described herein.

The laser array 500 may also include a first bonding pad 508, which may be used to electrically couple the laser array 500 to other electronic components and be used to control operation of the light emitters 502 and/or 504. For example, the first bonding pad 508 may be used to supply electric current to one or more light emitters 502 and/or 504 and cause the light emitters to emit light. The laser array 500 may also include a second bonding pad 510, which may be electrically coupled to one or more heating elements 520. The second bonding pad 510 may be used to supply electric current to a heating element 520, which may cause localized heating at that region of the array (e.g., due to resistive heating of the heating element 520). The separate bonding pad 510 may allow separate control of light emission and resistive heating of the laser array 500. For example, an electronic device may operate the heating elements 520 independent of the light emitters 502 and 504, which may allow heating to occur separately from emitting light or at the same time the light emitters 502, 504 are being operated to emit light from the laser array 500.

FIG. 5B shows a cross-sectional view taken along line B-B of the example surface emitting laser array 500 shown in FIG. 5A. The laser array 500 may be an example of the laser arrays described herein (e.g., laser arrays 108, 200, 400, etc.) and include a cathode layer 512, a first mirror structure 514 (e.g., a first DBR), a second mirror structure 516 (e.g., a second DBR), a laser cavity 518, and one or more anode pads 522. In some cases, one or more emitters (e.g., VCSEL structures) of the laser array 500 can have multiple active regions, which may also be referred to as a multi-junction VCSEL. The multiple active regions can be separated by multiple oxidation layers.

In some cases, the heating element 520 may be positioned on an upper surface of the laser array 500 and include one or more traces that electrically couple a respective heating element 520 to the second bonding pad 510. The heating element 520 may partially or completely surround a respective second emitter 504. Additionally or alternatively, a heating element 520 may be positioned over other portions of the laser array 500. For example, a heating element 520 may surround multiple light emitters, and/or be patterned to extend between multiple different light emitters (e.g., define a continuous path that traverses multiple light emitters). The connection of heating elements to the second bonding pad 510 can be established using any known methods of stacking multi-level interconnect metal and dielectric stacks.

The positioning, size, path and/or other parameters of the heating elements 520 may be configured to cause particular spatial shifts in the spectral emission across the laser array 500. For example, the heating elements 520 may be positioned throughout the laser array 500 to cause particular regions of the laser array 500 to have specific shifts in the emitted light.

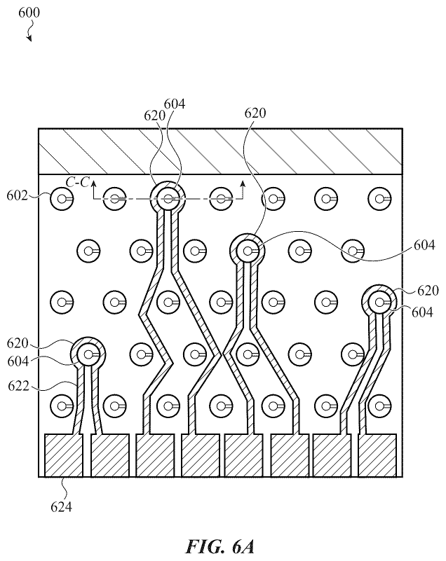

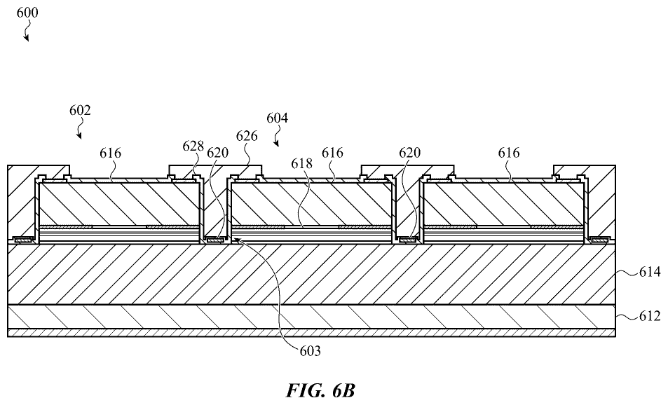

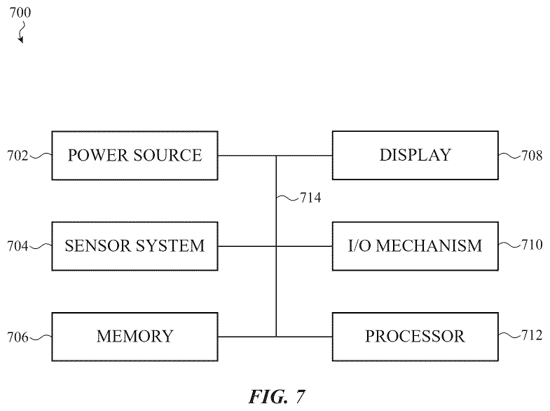

FIG. 6A shows a top view of example surface emitting laser array 600, as described herein. The laser array 600 may be an example of the laser arrays described herein (e.g., laser arrays 108, 200, 400, 500, etc.). The laser array 600 may include first light emitters 602 and second light emitters 604 that include heating elements 620 that are integrally formed within one or more layers of the laser array 600. The heating elements 620 may include a heating portion that extends around a respective second light emitter 604 and one or more traces 622 (one of which is labeled) that couples a heating element 620 to one or more electrodes 624 (one of which is labeled).

The heating element 620 may include a material that generates heat in response to an applied current. For example, the heating element 620 may include a higher resistance material such as a metal material that is embedded within the layers of the laser array 600. Example metal materials include gold, aluminum, titanium, nickel chromium, tungsten, metal alloys, and/or any other suitable metal materials. In some cases, the heating element 620 may include other materials such as ceramics, dielectric materials, polymers and/or other suitable non-metallic materials, and/or materials including both metals and non-metals. The heating elements 620 may be the same or different material than the traces 622 and the heating elements may be configured to generate substantially more heat than the traces 622.

The heating elements 620 may be configured to increase a local temperature of the laser array 600, as described herein. The localized heating of the laser array 600 may modify light emitted by the array, for example, increase a spectral width of light emitted from the laser array 600, as described herein. The positioning, size, path and/or other parameters of the heating elements 620 may be configured to cause a particular spatial shift in the spectral emission across the laser array 600. For example, the heating elements 620 may be positioned throughout the laser array 600 to cause particular regions of the laser array 600 to have specific shifts in the emitted light.

FIG. 6B shows a cross-sectional view taken along line C-C of the example surface emitting laser array 600 shown in FIG. 6A. The laser array 600 may be an example of the laser arrays described herein (e.g., laser arrays 108, 200, 400, 500, etc.) and include a cathode layer 612, a first mirror structure 614 (e.g., a first DBR), a second mirror structure 616 (e.g., a second DBR), a laser cavity 618, and one or more anode pads 626.

In the embodiment shown in FIGS. 6A and 6B, the heating element 620 is mounted in a trench area 603. For example, each light emitter 602, 604 may be at least partially surrounded by a trench that is formed in or defined by at least one or more layers of the second mirror structure 616, one or more layers of the laser cavity 618, and in some cases, one or more layers of the first mirror structure 614. The heating element 620 may be formed in the trench for example above one or more layers of the first mirror structure 614. In some cases, the heating element 620 may be positioned within a dielectric material 628 that is in the trench which may electrically isolate the heating element 620 from the anode pads 626. In some cases, the traces 622 may extend along the same layer of the laser array 600 to one or more electrodes 624. The anode pads 626 may be positioned above the heating elements 620 and extend to an upper surface of the laser array 600.

FIG. 7 shows an example block diagram 700 for an electronic device that can have one or more surface emitting laser arrays, as described herein. The electronic device 700 can include a processor 712, one or more sensors 704, memory 706, a display 708, an input/output (I/O) mechanism 710, and a power source 702.

The processor 712 can control some or all of the operations of the electronic device 700. The processor 712 can communicate, either directly or indirectly, with some or all of the components of the electronic device 700. For example, a system bus or other communication mechanism 714 can provide communication between, the processor 712, the one or more sensors 704, the memory 706, the display 708, the input/output (I/O) mechanism 710, and the power source 702.

The processor 712 can be implemented as any electronic device capable of processing, receiving, or transmitting data or instructions. For example, the processor 712 can be a microprocessor, a central processing unit (CPU), an application-specific integrated circuit (ASIC), a digital signal processor (DSP), or combinations of such devices. As described herein, the term “processor” is meant to encompass a single processor or processing unit, multiple processors, multiple processing units, or other suitable computing element or elements.

It should be noted that the components of the electronic device 700 can be controlled by multiple processors. For example, select components of the electronic device 700 (e.g., a sensor 704) may be controlled by a first processor and other components of the electronic device 700 (e.g., the I/O mechanism 710) may be controlled by a second processor, where the first and second processors may or may not be in communication with each other.

The electronic device 700 may also include one or more sensors 704 positioned almost anywhere on the electronic device 700. The sensor(s) 704 can be configured to sense one or more type of parameters, such as but not limited to, electrical signals, pressure, sound, light, touch, heat, movement, relative motion, biometric data (e.g., physiological parameters), and so on. For example, the sensor(s) 704 may include, one or more electrodes (and corresponding circuitry), a pressure sensor, an auditory sensor, a heat sensor, a position sensor, a light or optical sensor, an accelerometer, a pressure transducer, a gyroscope, a magnetometer, a health monitoring sensor, and so on. Additionally, the one or more sensors 704 can utilize any suitable sensing technology, including, but not limited to, capacitive, ultrasonic, resistive, optical, ultrasound, piezoelectric, and thermal sensing technology.

The memory 706 can store electronic data that can be used by the electronic device. For example, the memory 706 can store electrical data or content such as, for example, measured electrical signals, audio and video files, documents and applications, device settings and user preferences, timing signals, control signals, and data structures or databases. The memory 706 can be configured as any type of memory. By way of example only, the memory 706 can be implemented as random access memory, read-only memory, Flash memory, removable memory, other types of memory storage elements, or combinations of such devices.

The electronic device 700 may also include a display 708. The display 708 may include a liquid-crystal display (LCD), organic light-emitting diode (OLED) display, light-emitting diode (LED) display, or the like. If the display 708 is an LCD, the display 708 may also include a backlight component that can be controlled to provide variable levels of display brightness. If the display 708 is an OLED or LED type display, the brightness of the display 708 may be controlled by modifying the electrical signals that are provided to display elements. The display 708 may correspond to any of the displays shown or described herein.

The I/O mechanism 710 can transmit and/or receive data from a user or another electronic device. An I/O mechanism 710 can include a display, a touch sensing input surface, one or more buttons (e.g., a graphical user interface “home” button), one or more cameras, one or more microphones or speakers, one or more ports, such as a microphone port, and/or a keyboard. Additionally or alternatively, an I/O device or port can transmit electronic signals via a communications network, such as a wireless and/or wired network connection. Examples of wireless and wired network connections include, but are not limited to, cellular, Wi-Fi, Bluetooth, IR, and Ethernet connections.

The power source 702 can be implemented with any device capable of providing energy to the electronic device 700. For example, the power source 702 may be one or more batteries or rechargeable batteries. Additionally or alternatively, the power source 702 can be a power connector or power cord that connects the electronic device 700 to another power source, such as a wall outlet.

The present disclosure contemplates that the entities responsible for the collection, analysis, disclosure, transfer, storage, or other use of personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (“HIPAA”); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of determining spatial parameters, the present technology can be configured to allow users to select to “opt in” or “opt out” of participation in the collection of personal information data during registration for services or anytime thereafter. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, haptic outputs may be provided based on non-personal information data or a bare minimum amount of personal information, such as events or states at the device associated with a user, other non-personal information, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device, comprising:
a surface emitting laser array comprising:
a first set of light emitters distributed across the surface emitting laser array and configured to emit laser light into an environment of the electronic device; and
a second set of light emitters interspersed with the first set of light emitters, each light emitter in the second set of light emitters comprising:
a first set of layers defining a first mirror;
a second set of layers defining a second mirror; and
a third set of layers positioned between the first set of layers and the second set of layers and defining a laser cavity; and
a light blocking material positioned on one or more light emitters of the second set of light emitters and configured to reflect light generated by a respective light emitter of the second set of light emitters back into the surface emitting laser array.

2. The electronic device of claim 1, wherein:
each light emitter of the second set of light emitters comprises:
an electrical contact positioned on the third set of layers and defining an opening configured to allow laser light to be emitted from a respective light emitter; and
the light blocking material comprises a metal material positioned at least partially within the opening defined by the electrical contact.

3. The electronic device of claim 1, wherein:
the first set of light emitters is configured to be operated independently of the second set of light emitters;
applying electrical current to the first set of light emitters causes the laser light to be emitted from the surface emitting laser array; and
applying electrical current to the second set of light emitters causes localized heating of the surface emitting laser array.

4. The electronic device of claim 3, wherein:
the localized heating of the surface emitting laser array modifies an operating temperature of at least one light emitter of the first set of light emitters; and
the modified operating temperature causes a change in a wavelength of light emitted by at least one light emitter of the first set of light emitters.

5. The electronic device of claim 4, wherein the modified operating temperature causes an increase of a spectral width of light emitted from the surface emitting laser array.

6. The electronic device of claim 1, further comprising a processor, wherein the processor is configured to:
cause the first set of light emitters to be operated during a first time period; and
cause the second set of light emitters to be operated during a second time period, different from the first time period.

7. The electronic device of claim 6, wherein the first time period and the second time period are at least partially overlapping.

8. The electronic device of claim 1, wherein emitters of the surface emitting laser array comprise vertical cavity surface emitting lasers, horizontal cavity surface emitting lasers, or a combination thereof.

9. A surface emitting laser array comprising:
a first set of light emitters distributed across the surface emitting laser array and configured to emit laser light; and
a second set of light emitters interspersed with the first set of light emitters and configured to emit laser light, each light emitter in the second set of light emitters comprising:
a first set of layers defining a first mirror;
a second set of layers positioned on the first set of layers, defining a laser cavity and a first portion of a trench at least partially surrounding a respective light emitter;
a third set of layers positioned on the second set of layers, defining a second mirror, and a second portion of the trench; and
a heating element positioned within the trench and configured to adjust an operating temperature of one or more light emitters of the second set of light emitters.

10. The surface emitting laser array of claim 9, wherein:
the trench extends around a respective light emitter of the second set of light emitters; and
the heating element extends at least partially along the trench.

11. The surface emitting laser array of claim 9, wherein:
the first set of light emitters comprises first electrical contacts configured to provide electrical energy to light emitters of the first set of light emitters; and
the second set of light emitters comprises a second electrical contact configured to provide electrical energy to the second set of light emitters.

12. The surface emitting laser array of claim 11, wherein the surface emitting laser array comprises:
first traces coupled to the first electrical contacts;
a second trace coupled to the second electrical contact; and
a third trace coupled to the heating element.

13. The surface emitting laser array of claim 9, wherein the heating element comprises a metal material.

14. The surface emitting laser array of claim 9, wherein the trench extends at least partially into the first set of layers.

15. The surface emitting laser array of claim 9, wherein operation of the heating element is configured to increase a spectral width of light emitted from the surface emitting laser array.

16. An electronic device, comprising:
a surface emitting laser array comprising:
a first set of light emitters distributed across the surface emitting laser array, comprising first electrical contacts and configured to emit laser light; and
a second set of light emitters interspersed with the first set of light emitters, each light emitter in the second set of light emitters comprising:
a first set of layers defining a first mirror;
a second set of layers positioned on the first set of layers and defining a laser cavity;
a third set of layers positioned on the second set of layers and defining a second mirror;
a second electrical contact positioned on the third set of layers and defining an opening configured to allow laser light to be emitted from a respective light emitter;
a heating element positioned on the third set of layers and configured to increase an operating temperature of a respective emitter of the second set of light emitters; and
a processor configured to control operation of the first set of light emitters, the second set of light emitters and the heating element of the second set of light emitters.

17. The electronic device of claim 16, wherein each heating element of the second set of light emitters at least partially surrounds a respective light emitter of the second set of light emitters.

18. The electronic device of claim 16, wherein each heating element comprises a metal material that is electrically isolated from each second electrical contact.

19. The electronic device of claim 16, wherein operation of heating elements of the second set of light emitters is configured to increase a spectral width of light emitted from the surface emitting laser array.

20. The electronic device of claim 16, wherein the processor is configured to independently control operation of light emitters of the second set of light emitters and a respective heating element.
